(19) United States
(12) Patent Application Publication
(10) Pub. No.: US 2005/0275405 A1
(43) Pub. Date: Dec. 15, 2005

(54) Switching matrix apparatus for semiconductor characteristic measurement apparatus

(75) Inventor: Tomonobu Hiramatsu, Musashino-shi (JP)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/133,682

(22) Filed: May 20, 2005

(30) Foreign Application Priority Data
May 31, 2004 (JP) 2004-160493

(51) Int. Cl. G01R 31/02; G01R 31/327

(52) U.S. Cl. 324/415; 324/418

(57) ABSTRACT

A switching matrix apparatus includes relay switches for opening/closing the electrical connections between input lines and output lines and an LED matrix in which LEDs are arranged in a matrix so as to correspond to the respective relay switches. Each LED distinctively indicates a status, defined by the combination of the open/closed state of each relay switch corresponding to the LED and an instruction attribute for specifying opening/closing, by using a plurality of emitted light colors. The LEDs indicate whether or not the user can set the combinations of inputs and outputs.

### BACKGROUND OF THE INVENTION

1. Field of the Invention

The present invention relates to a switching matrix apparatus for semiconductor-characteristic measurement. In particular, the present invention relates to a switching matrix apparatus that can connect input ports and output channels in arbitrary combinations.

2. Description of the Related Art

Conventionally, a switching matrix apparatus is used to quickly change the connection between multiple semiconductor-characteristic measurement apparatuses and a device under test (hereinafter referred to as a “DUT”). The switching matrix apparatus connects input ports and output channels in arbitrary combinations in accordance with an instruction from a user. In this case, depending on the kind of measurements, one or more semiconductor-characteristic measurement apparatuses, including an LCR (inductance-capacitance-resistance) meter, are connected to the input ports and a probe apparatus or the like to be connected to the DUT is connected to the output channels. The input ports and the output channels are connected via relay switches and the electrical connections between the input ports and the output channels are opened or closed by the relay switches. The open/closed state of each relay switch is specified by the user each time.

Examples of such a switching matrix include a switching matrix 707A commercially available from Keithley Instruments Inc. For the description of this product, reference is made to the following documents: Keithley Instruments Inc., “Keithley's Switching Systems for Switch and Control Solutions for DC, RF, and Light” available from URL:http://www.keithley.com/main.jsp?action=keithleysearch&s earchType=view&clickPath=Document+Center&itemType=brochure&r ole=&keywords=707A, found on May 17, 2004; and the catalog of Keithley Instruments Inc., “Model 707A, Switching Matrix Mainframe with Fixed Rack Kit”, available from URL:http://www.keithley.com/main.jsp?action=keithleysearch&s earchType=view&clickPath=Document+Center&itemType=data+sheet &role=&keywords=707A, found on May 17, 2004.

This switching matrix product has a display unit that uses LEDs (light-emitting diodes) to indicate which input port and output channel are connected to each other. A light pen can optionally be used with the product. When the tip of the light pen is located on an LED corresponding to the intended relay switch and a button provided on the body of the light pen is pressed, the LED on which the light pen is located is detected. This makes it possible to selectively open and close the corresponding relay switch. The opening/closing of the relay switch is also indicated by turning on or off the corresponding LED.

The known switching matrix product described above indicates the states of the relay switches by using the LEDs, but has a problem. Specifically, the user cannot know whether each relay switch is in a state specified by the user or in a state specified by software.

### SUMMARY OF THE INVENTION

Accordingly, an object of the present invention is to overcome the problem described above.

The present invention provides a switching matrix apparatus used for connecting a semiconductor-characteristic measurement apparatus and a device under test. The switching matrix apparatus includes input terminals for connection with the semiconductor-characteristic measurement apparatus, output terminals for connection with the device under test, input lines connected to the respective input terminals, and output lines connected to the respective output terminals. The switching matrix apparatus further includes relay switches provided in a matrix to open and close electrical connections between the input lines and the output lines, and a light-emitting-portion matrix in which a plurality of light-emitting portions are arranged in a matrix so as to correspond to the respective relay switches. A combination of the open/closed state of the relay switches is changed to alter the combination of the electrical connections of the input lines and the output lines. Each light-emitting portion distinctively indicates a status, defined by a combination of the open/closed state of the relay switch corresponding to the light-emitting portion and an instruction attribute for specifying opening/closing of the relay switch, by using a plurality of emitted light colors.

In the present invention, preferably, one of the emitted light colors indicates the fact that the relay switch corresponding to the light-emitting portion is closed, to indicate which input terminal and output terminal are electrically connected to each other.

In the present invention, the switching matrix apparatus may further include controller for controlling the open/closed state of the relay switches, associated with the output terminals, in accordance with an attribute specified for each output terminal. Preferably, the plurality of emitted light colors include a color indicating the fact that the open/closed state of the relay switches is controlled by the controller in accordance with the specified attribute.

The term “status” as used herein refers to a state defined by the combination of the open/closed state of each relay switch and the instruction attribute (as to, for example, whether the connection state when not in use by the user can be controlled by the apparatus) for putting the relay switch into the present open/closed state. For example, if the combination is expressed in such a way as (“the open/closed state”, “the instruction attribute”), the emission light colors in the present invention may represent the cases, for example, of (the open state, the apparatus does nothing after use by the user), (the open state, the apparatus performs control after use by the user), (the closed state, the apparatus does nothing after use by the user), and (the closed state, the apparatus performs control after use by the user). Since a relay switch that is open does not connect anything, the light-emitting portion such as the LED can also be turned off correspondingly. In the present invention, of those statuses, at least two statues are assigned different light colors. Also, at least one state can be assigned a non-light-emitting indication that does not involve any light emission. Regarding the manner in which the instruction attributes are distinguished, it may be a simple manner in which a user's explicit instruction and control by the apparatus are distinguished, or in more detailed example, it may include an additional distinction based on more detailed attribute of a control instruction from the apparatus. The instruction attribute in the present invention refers to an arbitrary attribute that may accompany an instruction for specifying the opening/closing of the relay switch and that may be logically distinguishable.

An attribute that represents “the apparatus performs control after use by the user” can have, for example, a plurality of modes. For example, the attribute may include a mode in which a corresponding output channel is connected to a bias application terminal to allow an external bias to be applied to the output terminal (i.e., a “bias enable mode”) and a mode in which an output channel is connected to an external ground terminal to allow matching with an external ground level (i.e., a “ground enable mode”). In this case, those modes can be indicated with emitted light of the same color or can be indicated with emitted light of colors different from each other. Different emitted light colors can be used to indicate a case in which switching by the user is disabled and a case in which switching by the user is enabled.

The switching matrix apparatus of the present invention may further include inputting apparatus used for an operation for selecting relay switches in cooperation with the indication of each light-emitting portion of the light-emitting-portion matrix. Preferably, the plurality of emitted light colors include a color indicating a target selectable by the inputting means to clearly indicate a relay switch that is a selectable target for the selecting operation by the inputting apparatus. When the user operates the opening/closing of the relay switches, any of the relay switches can be selected. At this point, the light-emitting portions corresponding to the selectable relay switches emit light in a color indicating that the relay switches are selectable. When the user desires to perform an opening/closing operation on a relay switch, the user recognizes which relay switch the operation is performed on in accordance with the color indicating the selectable relay switch and continues to carry out the opening/closing operation. When the user desires to perform an opening/closing operation on another relay switch, the user performs the opening/closing operation by using inputting means to shift the position of a target for selection so that a light-emitting portion corresponding to the intended relay switch displays a color indicating that the target is selected. In this case, the inputting apparatus may be a light pen, and the inputting apparatus may be at least one key.

When the apparatus is combined with a display unit that displays different colors, it is possible to clearly indicate a currently-selected relay switch by using a color different from the color for the other relay switches, as well as indicating the state of the relay switch. Thus, the user can easily identify a switch to be selected for an opening/closing operation.

In the present invention, preferably, at least one of the light emitting portions is a group-state-indicating light-emitting portion for indicating a state of each group of the plurality of relay switches.

Provision of the light-emitting portions that indicate the states of the relay switches belonging to each group facilitates the identification of the indications even when a large number of input ports and output channels are switched.

The status indicated or distinguished by color emitted by the light emitting portions in the present invention can also be defined by the combination of a selection by the inputting apparatus and an instruction for specifying the opening/closing of the relay switch corresponding to each light-emitting portion.

According to the switching matrix apparatus of the present invention, the user can know the status of a relay switch for defining electrical connection between an input port and an output channel, which connection he or she intending to specify.

Also, provision of the light-emitting portions that indicate the states of the relay switches belonging to each group facilitates the identification of the indications even when a large number of input ports and output channels are switched.

### BRIEF DESCRIPTION OF THE DRAWINGS

FIG. 1 is a block diagram showing the configuration of a switching matrix apparatus according to an embodiment of the present invention;

FIG. 2 is a block diagram showing the configuration of relay switches of the switching matrix apparatus according to the embodiment of the present invention;

FIG. 3 is a block diagram showing the configuration of the switching matrix apparatus according to the embodiment of the present invention; and

FIG. 4 is a block diagram showing the configuration of a modification of the relay switches of the switching matrix apparatus according to the embodiment of the present invention.

### DESCRIPTION OF THE PREFERRED EMBODIMENT

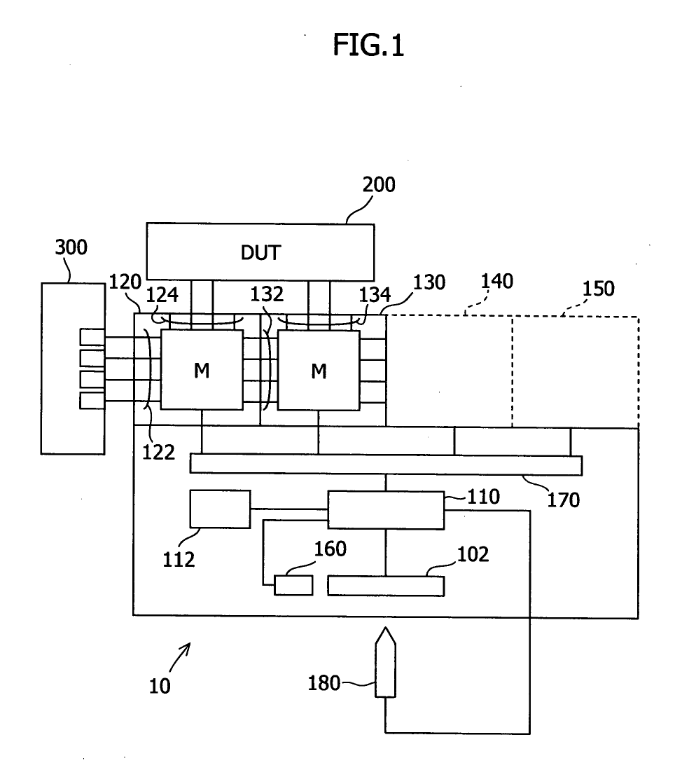

An embodiment of the present invention will be described below with reference to the accompanying drawings. FIG. 1 is a block diagram showing the configuration of a switching matrix apparatus 10 according to an embodiment of the present invention. The switching matrix apparatus 10 of the present embodiment controls connections between a semiconductor-characteristic measurement apparatus 300, such as an LCR meter, and a device under test (DUT) 200, which is probed by a probe apparatus (not shown) or the like.

The switching matrix apparatus 10 of the embodiment of the present invention includes a first card 120 and a second card 130, which have row terminals 122 and 132 and column terminals 124 and 134, respectively. In this case, for simplicity, the row terminals 122 are connected to the semiconductor-characteristic measurement apparatus 300 and the column terminals 124 and 134 are connected to the DUT 200. That is, in the switching matrix apparatus 10, the row terminals 122 serve as input terminals for connection with the semiconductor-characteristic measurement apparatus 300 and the column terminals 124 serve as output terminals for connection with the DUT 200. In this case, the row terminals 122 serve as input terminals and the column terminals 134 serve as output terminals to connect inputs and outputs via at least two relay switches. The row terminals 132 of the card 130 are connected to, for example, lines linked to the row terminals 122 of the card 120.

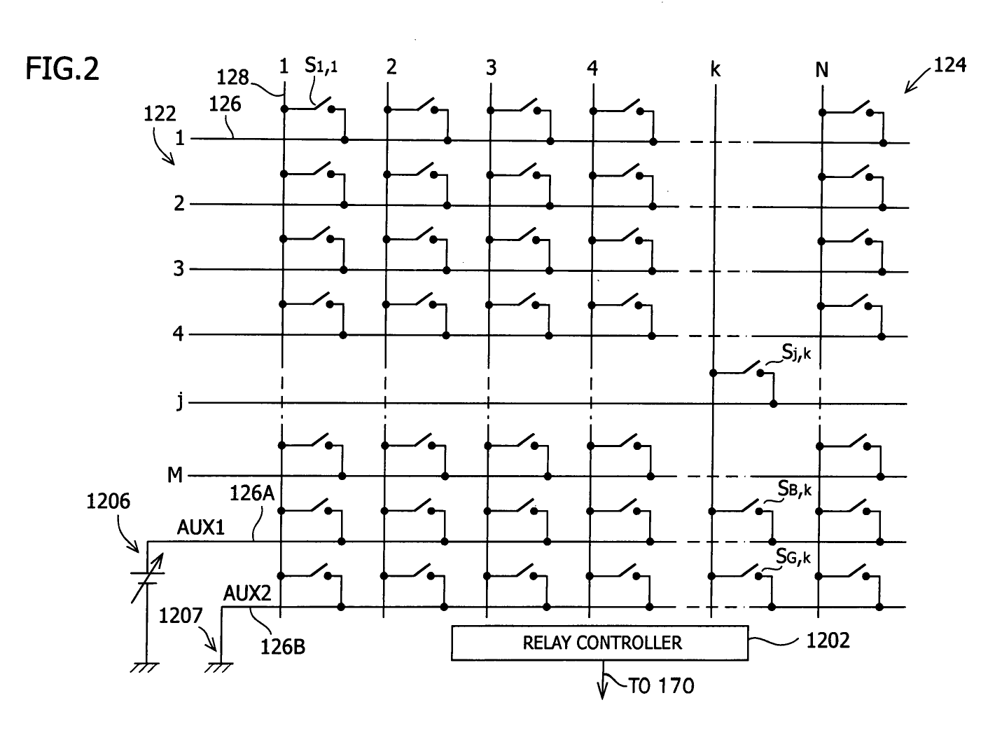

The cards 120 and 130 include row lines connected to the respective row terminals 122 and 132 and column lines connected to the respective column terminals 124 and 134. The cards 120 and 130 each include a plurality of relay switches in a matrix at the intersections of the row lines and the column lines. In FIG. 1, each matrix of relay switches is generally indicated as a matrix M. The relay switches open or close the electrical connections between the row lines and the corresponding column lines. Details of the cards 120 and 130 are described below with reference to FIG. 2. The switching matrix apparatus 10 may include card slots 140 and 150 into which additional cards, each having a matrix of relay switches, can be connected.

The switching matrix apparatus 10 of the embodiment of the present invention has a display unit 102 using LED (light emitting diode) matrix, in which a plurality of LEDs are arranged in a matrix as light-emitting portions so as to correspond to the respective relay switches. The switching matrix apparatus 10 of the embodiment of the present invention changes the combinations of the opening/closing of the relay switches to thereby switch the combinations of the electrical connections between the input lines and the output lines. As well as LEDs, any light emitters, such as plasma light emitters, can be used for the light-emitting portions.

Using a plurality of emitted light colors, each LED of the display unit 102 distinctively indicates a status, defined by the combination of the open/closed state of the relay switch corresponding to the LED and an instruction attribute for specifying the type of opening/closing operation.

The switching matrix apparatus 10 of the embodiment of the present invention further includes keys 160 and a memory 112. The keys 160 are used to move a cursor representing a relay switch of interest and the memory 112 is used to store settings such as the combinations of the relay switches. In response to an input from the keys 160, the controller 110 controls each of the cards 120 and 130 via a bus 170, receives setting information from the card, and causes the display unit 102 to display the current statuses of the relay switches.

FIG. 2 is a block diagram showing an overview of the configuration of the first card 120. The second card 130 also has a similar configuration. The first card 120 has M channels of row terminals 122 (M is an integer from 2 or more), which are connected to respective row input lines 126. The card 120 also has N channels of column terminals 124 (N is an integer from 2 or more), which are connected to respective column output lines 128. As shown in FIG. 2, connection points that define the connections of the input lines 126 and the output lines 128 have relay switches Sj,k in a matrix. In this case, j is an integer of 1 to M to represent the position of each row input line 126 and k is an integer of 1 to N to represent the position of each column output line 128. The relay switches Sj,k are controlled independently of each other by a relay controller 1202. The relay controller 1202 communicates with the controller 110 of the switching matrix apparatus 10 via the bus 170.

The row lines 122 are provided with terminals AUX1 and AUX2, relay switches SB,k, and relay switches SG,k. The terminals AUX1 and AUX2 connect a bias power source and ground to row terminals. A bias voltage source 1206 is connected to the terminal AUX1, so that a line 126A serves as a bias line, and ground 1207 is connected to the terminal AUX2, so that a line 126B serves as a ground line. The relay switches SB,k can electrically connect the line 126A to the corresponding column lines 128 and the relay switches SG,k can electrically connect the line 126B to the corresponding column lines 128. The lines 126A and 126B allow the column lines to be selectively connected to the bias voltage source 1206 and the ground 1207. This arrangement allows a line unused for connection with the input terminal and output terminal to be connected to a specific bias voltage or a ground voltage, thereby making it possible to reduce measurement noise and/or signal-settling time.

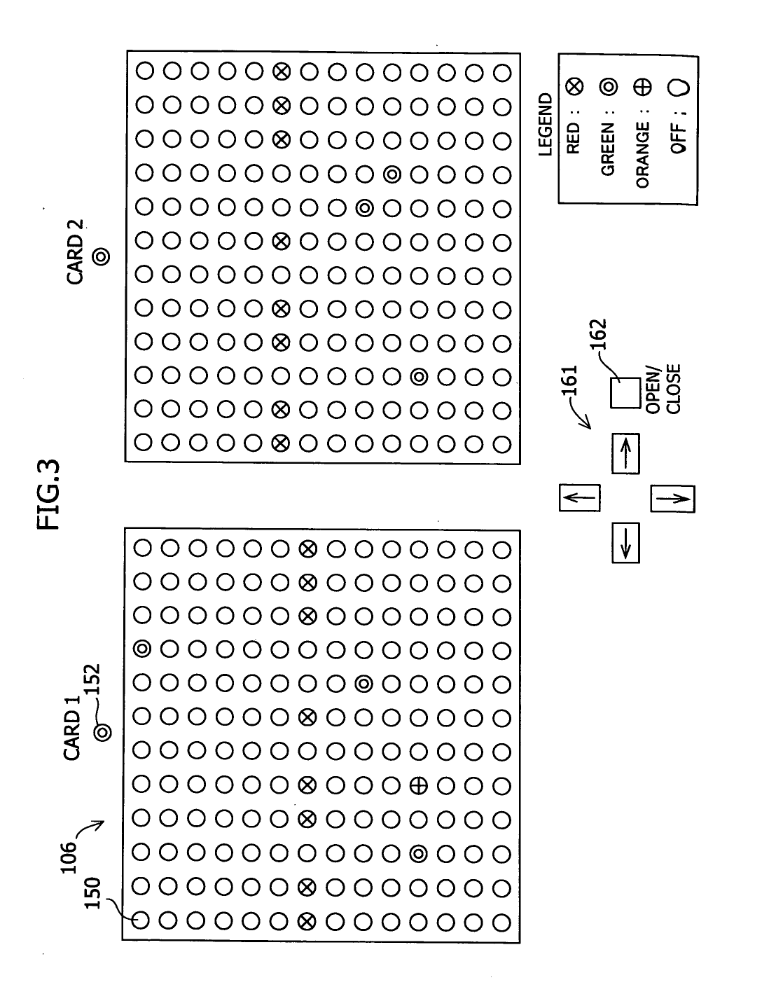

The operation of the keys 160 and the display of an operation panel on the display unit 102 of the switching matrix apparatus 10 according to the present embodiment will now be described with reference to FIG. 3. The display unit 102 has an array of LEDs 150 for each card. Using a plurality of emitted light colors, each of the LEDs distinctively indicates a status defined by the combination of the open/closed state of each relay switch Sj,k shown in FIG. 2 and an instruction attribute for specifying the open/closed state.

The intersections of the row lines 126 and the column lines 128 have the following four statuses:
Status (1) in which the connection is established (i.e., is closed) in response to a user's explicit instruction for connection;
Status (b 2) in which the connection is provided between the bias line and an output line declared as a bias enable line;
Status (3) in which the connection is provided between the ground line and an output line declared as a ground enable line; and
Status (4) in which the connection is not established (i.e., is open)

Of the four statuses described above, in status (4), the relay switch is open, and in statuses (1) to (3), the relay switch is closed. In statuses (2) and (3), the relay switch is closed without the user's explicitly specifying so.

More specifically, with respect to the input lines 126, the user first designates or specifies a bias port or a ground port for use as a bias line or a ground line by using a command or the like. Next, with respect to the output lines 128, the user uses a command or the like to designate or specify that an output line desired for connection to the bias line or the ground line when not in use is bias enabled or ground enabled, thereby determining the attribute of each output line. Control software for the apparatus controller 110 that operates in accordance with the declarations automatically connects an output line 128 that is not in use to the contact of the bias line 126A or the ground line 126B. However, when the user explicitly specifies that the output line is connected to an input line other than the input line previously specified above as bias ports or ground ports, the controller 110 disconnects the contact that is based on those attributes and closes a contact for connection with the input line specified by the user. Thereafter, the user explicitly disconnects the connection between the bias-enabled output line or ground-enabled output line and the input line specified by the user. The controller 110 then connects a contact in accordance with the attribute previously declared.

In the switching matrix apparatus 10 of the present embodiment, the connection of the contact corresponding to status (1) described above is indicated by green light emitted by the LEDs and the connections corresponding to statuses (2) and (3) are indicated by red light emitted by the LEDs. Thus, when different colors are used for the color displayed by the LEDs, the user can recognize whether a relay switch of interest is open through his or her selection or under the control of a program. In the case of status (4), the LED is turned off. In the switching matrix apparatus 10 of the present embodiment, the user can use cursors keys 161 to perform an operation for selecting a relay switch and can use an open/close key 162 to input a command for connecting/disconnecting the relay switch. In response to the user's operation, the switching matrix apparatus 10 displays different colors for clearly indicating which relay switch is specified with the cursor. In summary, indications corresponding to the statuses of each relay switch in the display unit 102 of the switching matrix apparatus 10 of the present embodiment are expressed as in Table 1.

TABLE 1

| LED Status | Meaning |
|---|---|
| Off | A relay switch corresponding to an LED of |
| | interest is open. |
| Green | A relay switch corresponding to an LED of |
| | interest is closed by a connection command |
| | issued by the user. |
| Red | A relay switch corresponding to an LED of |
| | interest is automatically closed by control |
| | software in the apparatus in accordance with |
| | an attribute specified by the user. |
| Orange | This indicates a current cursor position when the |
| | switching matrix is interactively controlled |
| | using the LED matrix. |

In a modification of the present invention, for example, rather than the instruction attribute, the combination of the open/closed state of a relay switch and whether or not a relay switch is a selectable target during selection using, for example, the cursor keys 161 to specify opening/closing can also be used to determine the color to be displayed. In this case, for example, when the relay switch is open and is not selectable, the light is turned off; when the relay switch is closed and is not selectable, the green light is turned on; when the relay switch is open and is selectable, the red light is turned on; and when the relay switch is closed and is selectable, the orange light is turned on. With this arrangement, for a selectable relay switch, the user can easily determine whether the relay switch is open or closed by taking a look at the emitted light color, namely, red or orange.

The switching matrix apparatus 10 of the present embodiment has LEDs 152 that indicate the (e.g., normal/malfunction) states of the respective cards. Each LED may be used to indicate the status of each card such that, for example, light turned off indicates a state in which the card is not installed, red light turned on indicates that a diagnosis process has found a failure in the card, and green light turned on indicates a state in which the card can be properly used.

In addition to the keys 160, a light pen 180 (shown in FIG. 1) can also be used to input information to the switching matrix apparatus 10 of the present embodiment. The light pen 180 has a tip for giving instructions, which tip incorporates a light-receiving element. The light pen 180 also has a signal line for transmitting an electrical signal generated by light detection to the controller 110 of the switching matrix apparatus 10. Various types of light pen can be used for the light pen 180. Examples include a light pen in which a mechanical switch is operated upon depression of the tip to thereby transmit a user-indicated target as an electrical signal and a light pen in which a button or switch that can be depressed by the user is provided on the main body of the light pen to thereby transmit a user-indicated target as an electrical signal. With the tip of the light pen 180, the user indicates an LED at a position corresponding to a relay switch that he or she desires to toggle. Upon detecting a user-indicated target through the electrical signal, the controller 110 turns on all the LEDs in a sequential scanning manner at slightly shifted timing. In accordance with the timing at which the receiving element portion of the light pen 180 receives light from each LED, the controller 110 identifies the LED indicated by the light pen 180, thereby detecting the pointed LED. The controller 110 then changes the open/closed state of a relay switch corresponding to that LED.

In this manner, the LEDs in the switching matrix apparatus of the present embodiment indicate a plurality of colors. Thus, the use of the switching matrix apparatus allows the user to readily recognize the software attributes given to the contacts of the switching matrix apparatus. In addition, the LED portion can be used as an input device together with keys or a light pen, thereby making it possible to interactively set the connection state of the switching matrix.

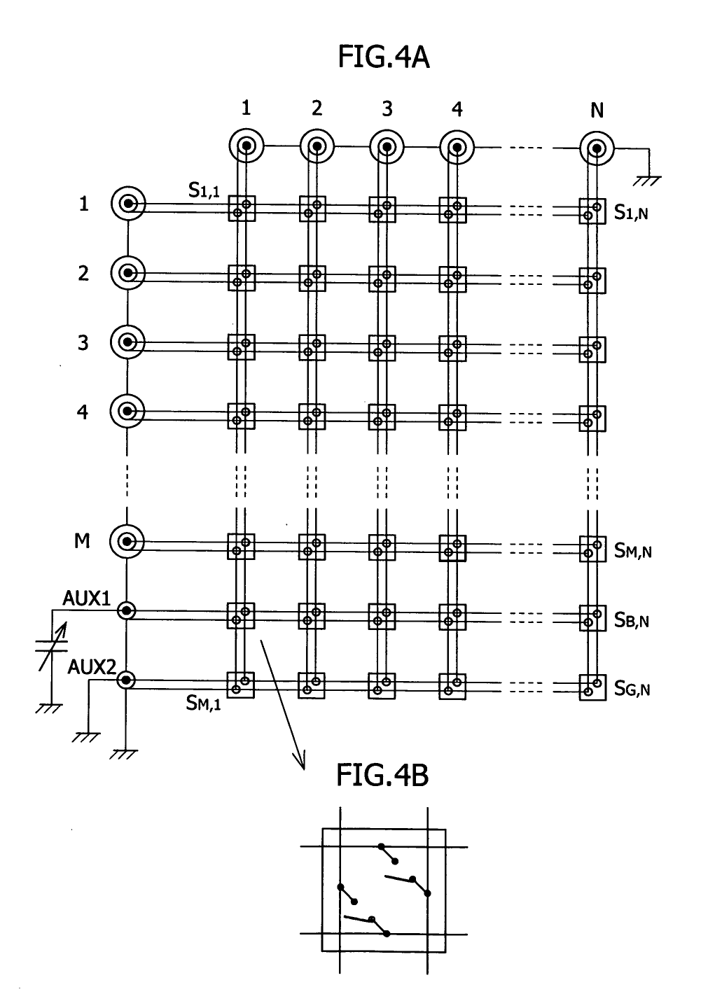

FIG. 4 is a block diagram showing an overview of the configuration of each card in a modification of the switching matrix apparatus of the embodiment. In this modification, triaxial connectors are used for the input and output terminals. As shown in part (a) in FIG. 4, for the input and output terminals other than the input terminals AUX1 and AUX2, triaxial connectors in which a signal line, a guard line, and a common (ground) line are connected in that order from the core-line side are arranged. The input lines and output lines are each constituted by a line having a signal line and a guard line. The signal lines and the guard lines of the input lines and the output lines are connected via matrix relay switches (see part (b) in FIG. 4) that interconnect the signal lines and the guard lines of the input lines and the output lines.

1. A switching matrix apparatus used for connecting a semiconductor-characteristic measurement apparatus and a device under test, the switching matrix apparatus comprising:
input terminals for connection with the semiconductor-characteristic measurement apparatus;
output terminals for connection with the device under test;
input lines connected to the respective input terminals;
output lines connected to the respective output terminals;
relay switches, provided in a matrix, for opening and closing electrical connections between the input lines and the output lines; and
a light-emitting-portion matrix in which a plurality of light-emitting portions are arranged in a matrix so as to correspond to the respective relay switches,
wherein a combination of the open/closed state of the relay switches is changed to alter a combination of the electrical connections of the input lines and the output lines, and
each light-emitting portion distinctively indicates a status that is defined by a combination of the open/closed state of the relay switch corresponding to the light-emitting portion and an instruction attribute for specifying opening/closing of the relay switch, by using a plurality of emitted light colors.

2. The switching matrix apparatus according to claim 1, wherein one of the emitted light colors indicates that the relay switch corresponding to the light-emitting portion is closed, to indicate which input terminal and output terminal are electrically connected to each other.

3. The switching matrix apparatus according to claim 1, further comprising controller for controlling the open/closed state of the relay switches, associated with the output terminals, in accordance with an attribute specified for each output terminal,
wherein the plurality of emitted light colors include a color indicating that the open/closed state of the relay switches is controlled by the controller in accordance with the specified attribute.

4. The switching matrix apparatus according to claim 1, further comprising inputting apparatus used for an operation for selecting relay switches in cooperation with the indication of each light-emitting portion of the light-emitting-portion matrix,
wherein the plurality of emitted light colors include a color indicating a target selectable by the inputting apparatus to clearly indicate a relay switch that is a selectable target for the selecting operation by the inputting means.

5. The switching matrix apparatus according to claim 4, wherein the inputting apparatus comprises a light pen.

6. The switching matrix apparatus according to claim 1, wherein the inputting apparatus comprises at least one key.

7. The switching matrix apparatus according to claim 1, wherein at least one of the light emitting portions comprises a group-state-indicating light-emitting portion for indicating a state of each group of the plurality of relay switches.

8. A switching matrix apparatus used for connecting a semiconductor-characteristic measurement apparatus and a device under test, the switching matrix apparatus comprising:
input terminals for connection with the semiconductor-characteristic measurement apparatus;
output terminals for connection with the device under test;
input lines connected to the respective input terminals;
output lines connected to the respective output terminals;
relay switches, provided in a matrix, for opening and closing electrical connections between the input lines and the output lines;
a light-emitting-portion matrix in which a plurality of light-emitting portions are arranged in a matrix so as to correspond to the respective relay switches; and
inputting means for performing an operation for selecting the relay switches in cooperation with an indication of each light-emitting portion of the light-emitting-portion matrix,
wherein a combination of the open/closed state of the relay switches is changed to change a combination of the electrical connections of the input lines and the output lines, and
each light-emitting portion distinctively indicates a status, defined by a combination of the open/closed state of the relay switch corresponding to the light-emitting portion and whether or not the relay switch is a target selectable by the inputting apparatus, by using a plurality of light colors emitted.
